(19) United States
(12) Patent Application Publication
(10) Pub. No.: US 2025/0120229 A1
(43) Pub. Date: Apr. 10, 2025

(54) LIGHT EMITTING DEVICE

(71) Applicant: TOYODA GOSEI CO., LTD., Kiyosu-shi (JP)

(72) Inventors: Aya KAWAOKA, Kiyosu-shi (JP); Takeshi MATSUSHIMA, Kiyosu-shi (JP); Hisayuki MIKI, Kiyosu-shi (JP)

(21) Appl. No.: 18/905,521

(22) Filed: Oct. 3, 2024

(30) Foreign Application Priority Data
Oct. 5, 2023 (JP) 2023-173356

(51) Int. Cl. H01L 33/58; H01L 33/22; H01L 33/48

(52) U.S. Cl. CPC H10H 20/855; H10H 20/82; H10H 20/8506

(57) ABSTRACT

A light emitting device includes a mounting substrate, a light emitting element emitting ultraviolet light, a light transmitting member forming an accommodation space in a region facing the mounting substrate and having a recess accommodating the light emitting element, an inert compound being a liquid at ordinary temperature and pressure, and a gas layer formed in the accommodation space. The inert compound is provided to fill a major region where a main surface of the light emitting element and a ceiling surface of the recess face each other, and a first subsidiary region where a portion of a side surface of the light emitting element closer to the main surface and a side wall surface of the recess face each other. The gas layer is formed in a second subsidiary region that faces a portion of the side surface of the light emitting element closer to the mounting substrate.

### CROSS-REFERENCE TO RELATED APPLICATIONS

This application is based on and claims priority under 35 USC 119 from Japanese Patent Application No. 2023-173356 filed on Oct. 5, 2023, the entire content of which is incorporated herein by reference.

### TECHNICAL FIELD

The present disclosure relates to a light emitting device.

### BACKGROUND ART

Light emitting devices using a light emitting element that emits ultraviolet light are used in various applications. For example, JP2016-127156A and JP2022-108692A disclose such a light emitting device having a configuration in which a light emitting element that emits ultraviolet light is mounted on a mounting substrate, and an ultraviolet light emitting side of the light emitting element is covered by a dome-shaped light transmitting member. In the configuration disclosed in JP2016-127156A, a space between an inner surface of the light transmitting member and a main surface on a side opposite to the mounting substrate and an entire side surface of surfaces of the light emitting element is filled with a liquid sealing material that transmits ultraviolet light, the sealing material is cured while a gap is formed between the light transmitting member and the mounting substrate. The gap prevents the sealing material before being cured from flowing out from between the light transmitting member and the light emitting element due to capillary action.

Further, in the configuration disclosed in JP2022-108692A, a space between an upper surface serving as a main surface of a light emitting element and an inner surface of a light transmitting member facing the upper surface is filled with a fluorocarbon compound that is a liquid at ordinary temperature and pressure, and an air layer exists between an entire side surface of the light emitting element and the inner surface of the light transmitting member. The liquid fluorocarbon compound is held between the main surface of the light emitting element and the inner surface of the light transmitting member by surface tension generated by the air layer, and is prevented from flowing out to a bonding portion between the light transmitting member and the mounting substrate.

In the configuration disclosed in JP2016-127156A, if the liquid sealing material is used without being cured at ordinary temperature and pressure, the liquid sealing material flows out to the gap between the mounting substrate and a cover due to the capillary action, and the sealing material is no longer held between the inner surface of the light transmitting member and the surfaces of the light emitting element. As a result, an air layer is formed between the inner surface of the light transmitting member and the main surface of the light emitting element, reducing an incidence rate of ultraviolet light emitted from the light emitting element into the light transmitting member, and therefore the efficiency of extracting ultraviolet light in the light emitting device decreases.

Further, in the configuration disclosed in JP2022-108692A, the air layer between the entire side surface of the light emitting element and the inner surface of the light transmitting member reduces an incidence rate of ultraviolet light emitted from the entire side surface of the light emitting element into the light transmitting member, and therefore the efficiency of extracting ultraviolet light in the light emitting device decreases.

### SUMMARY OF INVENTION

An object of the present disclosure is to provide a light emitting device capable of improving the efficiency of extracting ultraviolet light.

An aspect of the present disclosure provides a light emitting device that emits ultraviolet light, the light emitting device including:
a mounting substrate having a mounting surface;
a light emitting element disposed on the mounting surface of the mounting substrate and configured to emit ultraviolet light, the light emitting element having an element main surface facing a side opposite to the mounting surface and an element side surface adjacent to the element main surface;
a light transmitting member disposed on the mounting surface of the mounting substrate and configured to form an accommodation space in a region facing the mounting surface of the mounting substrate, the light transmitting member having a recess that forms at least a part of the accommodation space and accommodates at least a part of the light emitting element;
an inert compound disposed in the accommodation space and being a liquid at ordinary temperature and pressure; and
a gas layer formed in the accommodation space,
in which the inert compound is provided to fill a major facing region in which the element main surface of the light emitting element and a first ceiling surface of the recess face each other, and a first subsidiary facing region in which a portion of the element side surface of the light emitting element closer to the element main surface and a first side wall surface of the recess face each other, with the inert compound, and
the gas layer is formed in a second subsidiary facing region that faces a portion of the element side surface of the light emitting element closer to the mounting substrate.

In the light emitting device, the major facing region in which the element main surface and the first ceiling surface of the recess of the light transmitting member face each other, as well as the first subsidiary facing region in which the portion of the element side surface closer to the element main surface and the first side wall surface of the recess of the light transmitting member face each other are filled with the inert compound which is a liquid at ordinary temperature and pressure. Further, the gas layer is formed in the second subsidiary facing region facing the portion of the element side surface closer to the mounting substrate. Thus, the liquid inert compound with which the major facing region and the first subsidiary facing region are filled is prevented from flowing out due to the capillary action, by the gas layer formed in the second subsidiary facing region, and is held in the major facing region and the first subsidiary facing region. Accordingly, it is possible to prevent a decrease in the efficiency of extracting ultraviolet light emitted from the element main surface, and to improve the efficiency of extracting ultraviolet light emitted from at least the portion of the element side surface closer to the element main surface. Therefore, the efficiency of extracting ultraviolet light from the light emitting device as a whole can be improved.

As described above, according to the aspect of the present disclosure, it is possible to provide the light emitting device capable of improving the efficiency of extracting ultraviolet light.

### BRIEF DESCRIPTION OF DRAWINGS

Exemplary embodiment(s) of the present invention will be described in detail based on the following figures, wherein:

FIG. 1 is a cross-sectional view of a light emitting device taken along a plane orthogonal to a mounting substrate according to a first embodiment;

FIG. 2 is a conceptual cross-sectional view illustrating a configuration of a light emitting element according to the first embodiment;

FIG. 3 is an enlarged cross-sectional view of the vicinity of a second subsidiary facing region in FIG. 1;

FIG. 4 is a flowchart illustrating a manufacturing method for the light emitting device according to the first embodiment;

FIG. 5 is a conceptual diagram illustrating the manufacturing method for the light emitting device according to the first embodiment;

FIG. 6 is an enlarged cross-sectional view of the vicinity of a second subsidiary facing region according to a second embodiment; and

FIG. 7 is a cross-sectional view of a light emitting device taken along a plane orthogonal to a mounting substrate according to a third embodiment.

### DESCRIPTION OF EMBODIMENTS

A light emitting device emits ultraviolet light. The light emitting device includes:
a mounting substrate having a mounting surface;
a light emitting element disposed on the mounting surface of the mounting substrate and configured to emit ultraviolet light, the light emitting element having an element main surface facing a side opposite to the mounting surface and an element side surface adjacent to the element main surface;
a light transmitting member disposed on the mounting surface of the mounting substrate and configured to form an accommodation space in a region facing the mounting surface of the mounting substrate, the light transmitting member having a recess that forms at least a part of the accommodation space and accommodates at least a part of the light emitting element;
an inert compound disposed in the accommodation space and being a liquid at ordinary temperature and pressure; and
a gas layer formed in the accommodation space,
in which the inert compound is provided to fill a major facing region in which the element main surface of the light emitting element and a first ceiling surface of the recess face each other, and a first subsidiary facing region in which a portion of the element side surface of the light emitting element closer to the element main surface and a first side wall surface of the recess face each other, with the inert compound, and
the gas layer is formed in a second subsidiary facing region that faces a portion of the element side surface of the light emitting element closer to the mounting substrate.

A facing distance in the second subsidiary facing region is preferably longer than a facing distance in the first subsidiary facing region. In this case, the inert compound is easily held in the major facing region and the first subsidiary facing region, and the inert compound is prevented from flowing out to the second subsidiary facing region. Therefore, the efficiency of extracting ultraviolet light from the light emitting device as a whole can be further improved.

The inert compound is preferably held in the major facing region and the first subsidiary facing region by capillary action. In this case, a holding force of the inert compound in the major facing region and the first subsidiary facing region can be improved, the inert compound with which the major facing region and the first subsidiary facing region are filled can be further prevented from flowing out, and the efficiency of extracting ultraviolet light from the light emitting device 1 as a whole can be further improved.

A facing distance of the first subsidiary facing region is preferably longer than a facing distance of the major facing region. In this case, it is possible to further improve the holding force of the inert compound in the major facing region by the capillary action to further prevent the inert compound from flowing out, and to further improve the efficiency of extracting ultraviolet light from the light emitting device 1 as a whole.

A facing distance of the major facing region is preferably 0.1 μm to 500 μm, and a facing distance of the first subsidiary facing region is preferably 0.1 μm to 500 μm. In this case, it is possible to prevent the inert compound from flowing out by reliably generating the capillary action in the major facing region and the first subsidiary facing region, and to further improve the efficiency of extracting ultraviolet light from the light emitting device as a whole.

Arithmetic mean roughness Ra of a surface of the element side surface of the light emitting element forming the first subsidiary facing region is preferably 100 μm or less. In this case, a contact angle of the inert compound with respect to the element side surface decreases, and the wettability decreases. Therefore, the inert compound can be promoted to be held in the first subsidiary facing region by the capillary action.

The light emitting element is preferably formed in a shape that has no chip at a boundary between the element main surface and the element side surface. In this case, the inert compound held in the major facing region and the first subsidiary facing region can be further prevented from flowing out.

It is preferable that the element side surface of the light emitting element and the first side wall surface of the recess are formed in parallel. In this case, the inert compound held in the major facing region and the first subsidiary facing region can be further prevented from flowing out.

It is preferable that a side surface of an active layer of the light emitting element faces the first subsidiary facing region and faces the inert compound. In this case, as compared with a case where the side surface of the active layer that emits ultraviolet light faces the gas layer, the ultraviolet light emitted from the side surface of the active layer is incident on the light transmitting member via the inert compound and is easily output from the light transmitting member, so that the efficiency of extracting ultraviolet light from the light emitting device as a whole can be further improved.

A length of the first subsidiary facing region in a direction perpendicular to the mounting surface of the mounting substrate is preferably longer than a length of the second subsidiary facing region in the direction perpendicular to the mounting surface of the mounting substrate. In this case, the ultraviolet light emitted from the side surface of the active layer of the light emitting element is incident on the light transmitting member via the inert compound and is easily output from the light transmitting member, so that the efficiency of extracting ultraviolet light from the light emitting device as a whole can be further improved.

The light emitting element is preferably a flip chip type in which light is extracted from a back surface side of an element substrate included in the light emitting element. In this case, as compared to a face-up type, it is possible to further improve the efficiency of extracting ultraviolet light from the light emitting element itself, and as a result, it is possible to further improve the efficiency of extracting ultraviolet light from the light emitting device as a whole.

### First Embodiment

### 1. Configuration of Light Emitting Device 1

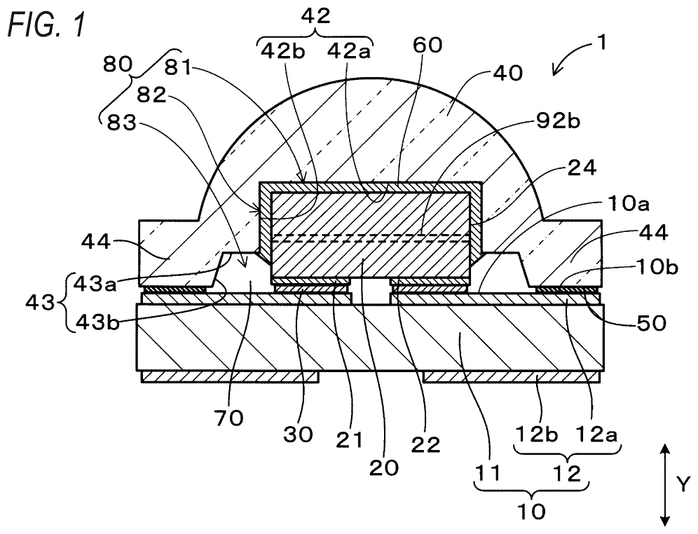

A configuration of a light emitting device 1 according to the embodiment will be described with reference to FIG. 1. The light emitting device 1 forms a light emitting element package in which a light emitting element 20 that emits ultraviolet light is accommodated as a main component. The light emitting device 1 that emits ultraviolet light includes a mounting substrate 10, the light emitting element 20, an element bonding layer 30, a light transmitting member 40, a light transmitting member bonding layer 50, an inert compound 60, and a gas layer 70.

The mounting substrate 10 has a mounting surface 10a, and is a substrate for mounting the light emitting element 20 on the mounting surface 10a. In this embodiment, the mounting substrate 10 is formed in a flat plate shape. Alternatively, the mounting substrate 10 may be formed in a case shape having a recessed portion.

The mounting substrate 10 includes a main body portion 11 and a circuit pattern 12. The main body portion 11 of the mounting substrate 10 is formed in a flat plate shape, for example. The main body portion 11 is formed to include at least one type of ceramic selected from the group consisting of, for example, AlN, Al₂O₃, SiC, and Si₂N₄. The circuit pattern 12 includes a first pattern portion 12a exposed on one surface of the main body portion 11 of the mounting substrate 10, a second pattern portion 12b exposed on the other surface (lower surface in FIG. 1) of the main body portion 11 of the mounting substrate 10, and a connection pattern portion (not shown) connecting the first pattern portion 12a and the second pattern portion 12b. A surface of the mounting substrate 10 closer to the first pattern portion 12a is the mounting surface 10a. A surface of the mounting substrate 10 closer to the second pattern portion 12b is a surface exposed to the outside. The second pattern portion 12b is a portion electrically connected to an external mounting substrate (not shown).

The light emitting element 20 contains a group III nitride, and emits ultraviolet light having a predetermined emission wavelength. The light emitting element 20 is a light emitting element that emits ultraviolet light having an emission wavelength of 100 nm to 400 nm (UVC band). In particular, the light emitting element 20 is a light emitting element that emits deep ultraviolet light having an emission wavelength of 100 nm to 280 nm. A thickness of the light emitting element 20 (thickness in an upper-lower direction in FIG. 1) is 1 μm or more.

The light emitting element 20 is mounted on the mounting surface 10a of the mounting substrate 10. In the embodiment, the light emitting element 20 is a flip chip type element including electrode pads 21 and 22 on a surface closer to the mounting substrate 10. Accordingly, the electrode pads 21 and 22 of the light emitting element 20 are positioned close to the mounting surface 10a of the mounting substrate 10, and are electrically connected to the first pattern portion 12a of the circuit pattern 12 of the mounting substrate 10 via the element bonding layer 30.

In the embodiment, the light emitting element 20 includes an element main surface 23 facing a side (upper side in FIG. 1) opposite to the mounting surface 10a of the mounting substrate 10, and an element side surface 24 located in a peripheral direction and adjacent to the element main surface 23. The element main surface 23 is formed in a planar shape parallel to the mounting surface 10a of the mounting substrate 10. The element main surface 23 is formed in a rectangular shape. The arithmetic mean roughness Ra of the element main surface 23 is 0.1 nm to 100000 nm.

The element side surface 24 is adjacent to each side of an outer periphery of the element main surface 23. The element side surface 24 has a surface substantially perpendicular to the mounting surface 10a of the mounting substrate 10. For example, the element side surface 24 has four surfaces adjacent to each side of the element main surface 23. The arithmetic mean roughness Ra of the element side surface 24 of the light emitting element 20 is 0.1 nm to 100000 nm.

In the light emitting element 20, an angle formed between the element main surface 23 and the element side surface 24 is in a range of 80° to 100°, and preferably 90°, over the entire outer periphery of the element main surface 23. The light emitting element 20 is formed in a shape that has no chip such as a notch or a dent at a boundary between the element main surface 23 and the element side surface 24 over the entire outer periphery of the element main surface 23.

The element bonding layer 30 bonds the first pattern portion 12a of the circuit pattern 12 of the mounting substrate 10 and the electrode pads 21 and 22 of the light emitting element 20. The material for the element bonding layer 30 includes, for example, AuSn, Au, Ag, Cu, Al, and SAC.

The light transmitting member 40 is disposed close to the mounting surface 10a of the mounting substrate 10. Specifically, the light transmitting member 40 is bonded to an outer peripheral edge of the mounting surface 10a of the mounting substrate 10 via the light transmitting member bonding layer 50. The light transmitting member 40 is a sealing material that defines an accommodation space 80 in a region facing the mounting surface 10a of the mounting substrate 10. The light emitting element 20 and the like are accommodated in the accommodation space 80.

The light transmitting member 40 may be made of any material that transmits ultraviolet light of the emission wavelength, and may be made of glass, for example. For example, the light transmitting member 40 is formed to include at least one type of glass selected from the group consisting of quartz, borosilicate, sapphire, fluoride, silicone resin, and metaphosphate. When the light transmitting member 40 is made of quartz, the refractive index of the light transmitting member 40 is 1.45.

Here, a bonding position between the light transmitting member 40 and the mounting substrate 10 (that is, a position of an outer peripheral edge 10b of the mounting substrate 10 to which a flange portion 44 of the light transmitting member 40 is bonded) is positioned closer to the mounting surface 10a of the mounting substrate 10 than the element main surface 23 of the light emitting element 20 in a direction perpendicular to the mounting surface 10a of the mounting substrate 10. Further, the bonding position between the light transmitting member 40 and the mounting substrate 10 is located closer to the mounting surface 10a of the mounting substrate 10 than the position of an active layer 92b of the light emitting element 20 in the direction perpendicular to the mounting surface 10a of the mounting substrate 10.

In the embodiment, the bonding position between the light transmitting member 40 and the mounting substrate 10 is located along the surface of the mounting surface 10a of the mounting substrate 10, while the active layer 92b is located at a distance from the mounting surface 10a. With such a configuration, as described above, the bonding position between the light transmitting member 40 and the mounting substrate 10 is positioned closer to the mounting surface 10a (lower side in FIG. 1) of the mounting substrate 10 than the position of the active layer 92b of the light emitting element 20.

The light transmitting member 40 has, for example, a convex lens shape. That is, an outer surface of the light transmitting member 40 is formed in a convex curved shape. By forming the light transmitting member 40 in a convex lens shape, the ultraviolet light emitted by the light emitting element 20 can be output mainly in the direction perpendicular to the mounting substrate 10.

The light transmitting member 40 includes a recess 41 that defines at least a part of the accommodation space 80 on the surface facing the mounting surface 10a of the mounting substrate 10. The recess 41 is configured to accommodate at least a part of the light emitting element 20. In the embodiment, the recess 41 is configured to accommodate the entire light emitting element 20. That is, the accommodation space 80 is formed between the recess 41 of the light transmitting member 40 and the mounting surface 10a of the mounting substrate 10.

The recess 41 has a first recess 42 and a second recess 43. The recess 41 forms a stepped recess by the first recess 42 and the second recess 43. The recess 41 may be configured as a stepped recess having three or more steps.

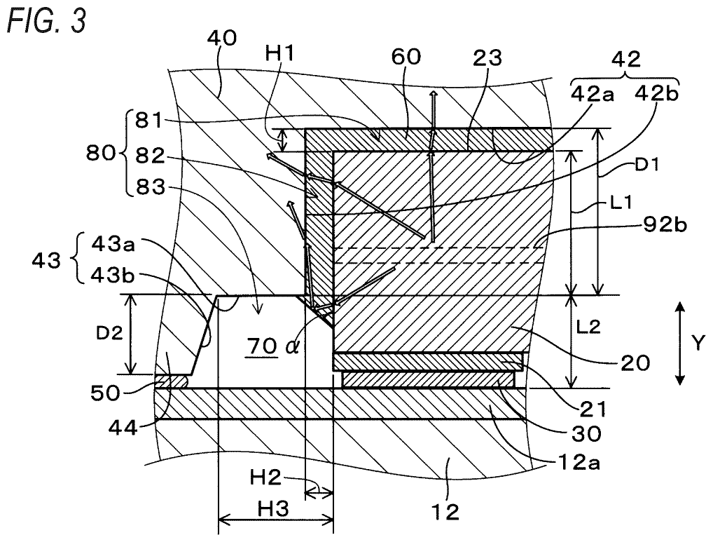

The first recess 42 is located in the center of the surface of the light transmitting member 40 that faces the mounting surface 10a of the mounting substrate 10. The first recess 42 is configured to accommodate one part of the light emitting element 20. A depth of the first recess 42 is shorter than a height of the light emitting element 20. In the embodiment, the depth of the first recess 42 is about half to two-thirds of the thickness of the light emitting element 20. A depth D1 of the first recess 42 shown in FIG. 3 is 10 μm to 1000 μm. The first recess 42 has a first ceiling surface 42a and a first side wall surface 42b.

The first ceiling surface 42a is formed in a planar shape parallel to the mounting surface 10a of the mounting substrate 10. The first ceiling surface 42a is formed in a rectangular shape. First ceiling surface 42a is disposed to face the element main surface 23 of light emitting element 20. Specifically, the first ceiling surface 42a is formed in parallel with the element main surface 23 of light emitting element 20, and is disposed at a predetermined distance from the element main surface 23. Accordingly, a major facing region 81 is formed in which the first ceiling surface 42a of the first recess 42 and the element main surface 23 of the light emitting element 20 face each other.

The first side wall surface 42b is adjacent to each side of an outer peripheral edge of the first ceiling surface 42a. The first side wall surface 42b has a surface substantially perpendicular to the mounting surface 10a of the mounting substrate 10. That is, the first side wall surface 42b has four surfaces adjacent to each side of the first ceiling surface 42a. Each surface of the first side wall surface 42b is formed parallel to a portion (portion on the upper side in FIG. 1) of the element side surface 24 of the light emitting element 20 closer to the element main surface 23, and is disposed at a predetermined distance from the portion of the element side surface 24 closer to the element main surface 23. Accordingly, a first subsidiary facing region 82 is formed in which the first side wall surface 42b of the first recess 42 and the portion (portion on the upper side in FIG. 1) of the element side surface 24 of the light emitting element 20 closer to the element main surface 23 face each other.

The second recess 43 is located on an opening side of the first recess 42, has an opening which is larger than an opening of the first recess 42, and has a ceiling surface which is shallower than that of the first recess 42. The second recess 43 is configured to accommodate the other part of the light emitting element 20. A depth of the second recess 43 is shorter than the height of the light emitting element 20. In the embodiment, the depth of the second recess 43 is about half the thickness of the light emitting element 20. A depth D2 of the second recess 43 shown in FIG. 3 is 10 μm to 1000 μm. The second recess 43 has a second ceiling surface 43a and a second side wall surface 43b.

The second ceiling surface 43a is formed in a planar shape parallel to the mounting surface 10a of the mounting substrate 10. The second ceiling surface 43a is adjacent to the first side wall surface 42b of the first recess 42. An outer peripheral shape of the second ceiling surface 43a may be rectangular or circular. The second ceiling surface 43a is formed in a ring shape. The second ceiling surface 43a is disposed to face the mounting surface 10a of the mounting substrate 10, and is disposed at a predetermined distance from the mounting surface 10a.

The second side wall surface 43b is adjacent to an outer peripheral edge of the second ceiling surface 43a. The second side wall surface 43b is angled with respect to the mounting surface 10a of the mounting substrate 10. For example, the second side wall surface 43b forms an inclined surface that forms an acute angle with respect to the mounting surface 10a. The second side wall surface 43b faces a portion (portion on a lower side in FIG. 1) of the element side surface 24 of the light emitting element 20 closer to the mounting substrate 10, and is disposed at a predetermined distance from the portion of the element side surface 24 closer to the mounting substrate 10. Accordingly, a second subsidiary facing region 83 is formed in which the second side wall surface 43b of the second recess 43 and the portion (portion on the lower side in FIG. 1) of the element side surface 24 of the light emitting element 20 closer to the mounting substrate 10 face each other.

The light transmitting member bonding layer 50 is disposed between the outer peripheral edge 10b of the mounting surface 10a of the mounting substrate 10 and the flange portion 44 forming the outer peripheral edge of the light transmitting member 40, and bonds the mounting surface 10a of the mounting substrate 10 and the light transmitting member 40. The light transmitting member bonding layer 50 is formed to include at least one selected from the group consisting of silicone resin, epoxy resin, fluororesin, solder, silane, glass, brazing material, and the like. In the first embodiment, the outer peripheral edge 10b is located on the same plane as the mounting surface 10a.

As described above, the bonding position between the light transmitting member 40 and the mounting substrate 10 is located (lower side in FIG. 1) closer to the mounting surface 10a of the mounting substrate 10 than the position of an active layer 92b of the light emitting element 20 in a direction Y perpendicular to the mounting surface 10a of the mounting substrate 10. That is, the light transmitting member bonding layer 50 is positioned closer to the mounting surface 10a of the mounting substrate 10 than the first subsidiary facing region 82. Further, the light transmitting member bonding layer 50 is positioned closer to the mounting surface 10a of the mounting substrate 10 than the position of the active layer 92b.

Therefore, even if the light transmitting member bonding layer 50 is made of a material that is not very durable against ultraviolet light of the emission wavelength, the effect is extremely small. Accordingly, the inexpensive materials mentioned above can be used for the light transmitting member bonding layer 50. Of course, the light transmitting member bonding layer 50 may be made of a material that is highly durable against ultraviolet light, such as silicone resin.

The inert compound 60 is disposed in the accommodation space 80 defined by the mounting substrate 10 and the light transmitting member 40. The inert compound 60 is disposed in the major facing region 81 and the first subsidiary facing region 82 of the accommodation space 80. That is, the major facing region 81 in which the first ceiling surface 42a of the first recess 42 and the element main surface 23 of the light emitting element 20 face each other is filled with the inert compound 60. Accordingly, the inert compound 60 is in contact with the first ceiling surface 42a of the first recess 42 and is also in contact with the element main surface 23 of the light emitting element 20.

Further, the first subsidiary facing region 82 in which the first side wall surface 42b of the first recess 42 and the portion of the element side surface 24 of the light emitting element 20 closer to the element main surface 23 face each other is filled with the inert compound 60. Accordingly, the inert compound 60 is in contact with the first side wall surface 42b of the first recess 42 and is also in contact with the portion of the element side surface 24 of the light emitting element 20 closer to the element main surface 23. A side surface of the active layer 92b of the light emitting element 20 faces the first subsidiary facing region 82. That is, the side surface of the active layer 92b of the light emitting element 20 faces the inert compound 60.

The inert compound 60 is a liquid at ordinary temperature and pressure. The inert compound 60 may be, for example, at least one selected from the group consisting of a fluoride compound, a silicon compound, and a phosphate compound.

As an example of the fluoride compound of the inert compound 60, for example, a fluorocarbon compound that is a polymer having a CF bond is preferable. The number of carbon atoms in the fluorocarbon compound is preferably 1.9 times or less the number of fluorine atoms in the fluorocarbon compound. Examples of the fluorocarbon compound include perfluoropolyether (PFPE) and hydrofluoroether (HFE).

The gas layer 70 is formed in the accommodation space 80 defined by the mounting substrate 10 and the light transmitting member 40. As described above, the light emitting element 20 and the inert compound 60 are disposed in the accommodation space 80. Accordingly, the gas layer 70 is disposed in at least a region of the accommodation space 80 excluding a region where the light emitting element 20 and the inert compound 60 are disposed.

Specifically, the gas layer 70 is formed in the second subsidiary facing region 83 in the accommodation space 80. That is, the gas layer 70 is formed in the second subsidiary facing region 83 in which the second side wall surface 43b of the second recess 43 and the portion of the element side surface 24 of the light emitting element 20 closer to the mounting substrate 10 face each other. That is, the gas layer 70 is in contact with the portion of the element side surface 24 of the light emitting element 20 closer to the mounting substrate 10. Further, the gas layer 70 is in contact with a part of the inert compound 60.

The gas layer 70 is formed by containing at least one gas selected from the group consisting of air, nitrogen, and carbon dioxide, for example. The refractive index of the gas layer 70 is less than the refractive index of the inert compound 60. In the first embodiment, the gas layer 70 is formed of air, and the refractive index of air is 1.0.

### 2. Configuration of Light Emitting Element 20

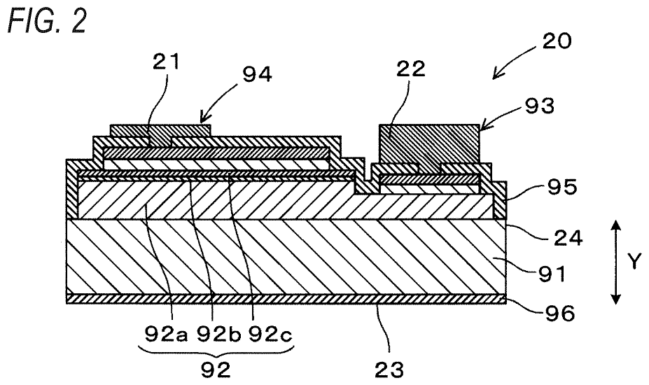

The configuration of the light emitting element 20 will be described with reference to FIG. 2. FIG. 2 is a diagram showing the configuration of the light emitting element 20, and is a cross-sectional view in the direction perpendicular to a main surface of the substrate. The light emitting element 20 according to the present embodiment is of a flip chip type in which light is extracted from a back surface of the substrate (surface opposite to the main surface of the substrate). Accordingly, the light emitting element 20 shown in FIG. 2 is a diagram obtained by turning the light emitting element 20 shown in FIG. 1 upside down.

The light emitting element 20 mainly includes an element substrate 91, a semiconductor layer 92, an n-side electrode 93, a p-side electrode 94, a protective layer 95, and an antireflection layer 96. The light emitting element 20 is of a flip chip type, and has a structure in which light is extracted from a surface closer to the element substrate 91 (lower surface in FIG. 2). The light emitting element 20 is a light emitting element for ultraviolet light emission having an emission wavelength of 100 nm to 400 nm, and in particular, is a light emitting element for deep ultraviolet light emission having an emission wavelength of 100 nm to 280 nm (UVC band).

The element substrate 91 is, for example, a substrate made of sapphire. Other than sapphire, the element substrate 91 may be made of any material as long as the material has a high transmittance with respect to the emission wavelength and allows crystal growth of a group III nitride semiconductor. For example, the element substrate 91 may be an AlN substrate or an AlN template substrate in which an AlN layer is formed on a sapphire substrate. When the element substrate 91 is made of sapphire, the refractive index of the element substrate 91 is 1.76. A thickness of the element substrate 91 is 1 μm or more, preferably 100 μm or more.

The semiconductor layer 92 is formed on a main surface of the element substrate 91 by crystal growth. The semiconductor layer 92 includes a group III nitride semiconductor. The semiconductor layer 92 includes at least an n-type layer 92a, an active layer 92b, and a p-type layer 92c. The semiconductor layer 92 is formed by stacking the n-type layer 92a, the active layer 92b, and the p-type layer 92c in this order from the element substrate 91.

The n-type layer 92a includes a group III nitride semiconductor. The n-type layer 92a is made of, for example, n-AlGaN. The active layer 92b includes a group III nitride semiconductor. The active layer 92b has an SQW structure in which a barrier layer, a well layer, and a barrier layer are stacked in this order from the n-type layer 92a. The active layer 92b may also have an MQW structure. The well layer contains AlGaN, and an Al composition therein is set according to a desired emission wavelength. The barrier layer contains AlGaN having an Al composition higher than that of the well layer, and the Al composition is, for example, 50% to 100%. The p-type layer 92c forms a layer in contact with an electrode, and is therefore also called a p-type contact layer. The p-type layer 92c includes a group III nitride semiconductor. The p-type layer 92c may include Mg-doped p-GaN or p-AlGaN.

The n-side electrode 93 is provided on and in contact with the n-type layer 92a. The n-side electrode pad 21 forming the n-side electrode 93 is provided in an exposed state. As shown in FIG. 1, the n-side electrode pad 21 is provided in contact with the first pattern portion 12a of the circuit pattern 12 of the mounting substrate 10. The p-side electrode 94 is provided on and in contact with the p-type layer 92c. The p-side electrode 94 includes a reflective layer that reflects ultraviolet light of the emission wavelength. Further, the p-side electrode pad 22 forming the p-side electrode 94 is provided in an exposed state. As shown in FIG. 1, the p-side electrode pad 22 is provided in contact with the first pattern portion 12a of the circuit pattern 12 of the mounting substrate 10.

The protective layer 95 is made of an insulating material and protects an upper and side surfaces of the semiconductor layer 92. A portion of the n-side electrode 93 is disposed so as to be exposed on the protective layer 95, and the n-side electrode 93 is electrically connected to the n-type layer 92a through a hole in the protective layer 95. A portion of the p-side electrode 94 is disposed so as to be exposed on the protective layer 95, and the p-side electrode 94 is electrically connected to the p-type layer 92c through a hole in the protective layer 95.

The antireflection layer 96 is provided on the back surface (the lower surface in FIG. 2, a surface from which the light is extracted) of the element substrate 91, and a surface of the antireflection layer 96 forms the element main surface 23. Alternatively, the antireflection layer 96 may not be provided. In this case, in the light emitting element 20, the back surface of the element substrate 91 is exposed to form the element main surface 23.

### 3. Detailed Description of Regions 81 to 83

The major facing region 81, the first subsidiary facing region 82, and the second subsidiary facing region 83 will be described in detail with reference to FIG. 3. The major facing region 81 is a region in which the first ceiling surface 42a of the first recess 42 and the element main surface 23 of the light emitting element 20 face each other. A facing distance H1 of the major facing region 81 is 0.1 μm to 500 μm, preferably 0.1 μm to 100 μm.

The first subsidiary facing region 82 is a region in which the first side wall surface 42b of the first recess 42 and the portion (portion on the upper side in FIG. 3) of the element side surface 24 of the light emitting element 20 closer to the element main surface 23 face each other. A facing distance H2 of the first subsidiary facing region 82 is longer than the facing distance H1 of the major facing region 81. The facing distance H2 of the first subsidiary facing region 82 is 0.1 μm to 500 μm, preferably 0.1 μm to 500 μm. In the embodiment, the first subsidiary facing region 82 faces the side surface of the active layer 92b of the light emitting element 20. Alternatively, the side surface of the active layer 92b of the light emitting element 20 may be covered with an insulating layer, and therefore may not be exposed. Accordingly, the side surface of the active layer 92b of the light emitting element 20 faces the first subsidiary facing region 82 via the insulating layer.

The second subsidiary facing region 83 is a region in which the second side wall surface 43b of the second recess 43 and the portion (portion on the lower side in FIG. 3) of the element side surface 24 of the light emitting element 20 closer to the mounting substrate face each other. A minimum facing distance H3 of the second subsidiary facing region 83 is longer than the facing distance H2 of the first subsidiary facing region 82. For example, the minimum facing distance H3 of the second subsidiary facing region 83 is equal to or greater than twice the facing distance H2 of the first subsidiary facing region 82. The facing distance H3 of the second subsidiary facing region 83 is 0.1 μm to 1000 μm, preferably 50 μm to 500 μm.

As shown in FIG. 3, a length L1 of the first subsidiary facing region 82 in the direction Y perpendicular to the mounting surface 10a of the mounting substrate 10 is longer than a length L2 of the second subsidiary facing region 83 in the direction Y perpendicular to the mounting surface 10a of the mounting substrate 10.

### 4. Details of Inert Compound 60

The inert compound 60 includes at least one selected from the group consisting of a fluoride compound, a silicon compound, and a phosphate compound. The viscosity of the inert compound 60 is 0.01 Pa·s to 50 Pas, preferably 0.1 Pa·s to 50 Pa·s. A contact angle of the inert compound 60 is from 0.1° to 150°, preferably 10° to 50°. As a result, the inert compound 60 is held in the major facing region 81 and the first subsidiary facing region 82 by the capillary action.

In particular, the arithmetic mean roughness Ra of the element side surface 24 of the light emitting element 20 is 0.1 nm to 100000 nm. This also allows the inert compound 60 to be held in the first subsidiary facing region 82 by the capillary action. Further, the light emitting element 20 is formed in a shape that has no chip such as a notch or a dent at the boundary between the element main surface 23 and the element side surface 24 over the entire outer periphery of the element main surface 23. Accordingly, the inert compound 60 is held in the major facing region 81 and the first subsidiary facing region 82.

The boiling point of the inert compound 60 is 100° C. or higher, preferably 260° C. or higher. The junction temperature Tj of the light emitting element 20 is set to be 150° C. or lower. Accordingly, even if the temperature of the light emitting element 20 rises, it is possible to prevent the inert compound 60 from being vaporized, and it is possible to maintain the state in which the inert compound 60 is held in the major facing region 81 and the first subsidiary facing region 82 by the capillary action.

The inert compound 60 has a transmittance of 50% or more, preferably 80% or more, for ultraviolet light having an emission wavelength of 280 nm. Further, the refractive index of the inert compound 60 is closer to the refractive index of the light transmitting member 40 than the refractive index of air. The refractive index of the inert compound 60 is closer to the refractive index of the element substrate 91 (shown in FIG. 2) of the light emitting element 20 than the refractive index of air. In the present embodiment, it is preferable that the refractive index of the inert compound 60 is greater than the refractive index of air and equal to or less than the refractive index of the light transmitting member 40 and the refractive index of the element substrate 91. When the inert compound 60 is a fluorocarbon compound, the refractive index of the fluorocarbon compound is, for example, 1.2 or more and 1.6 or less.

5. Shape of Boundary between Inert Compound 60 and Gas Layer 70

A shape of a boundary between the inert compound 60 and the gas layer 70 will be described with reference to FIG. 3. In the embodiment, the major facing region 81 and the first subsidiary facing region 82 are filled with the inert compound 60. Further, a small portion of the inert compound 60 enters the second subsidiary facing region 83 through an opening of the first subsidiary facing region 82. Accordingly, the boundary between the inert compound 60 and the gas layer 70 is located in the second subsidiary facing region 83.

The shape of the boundary depends on the viscosity and the contact angle of the inert compound 60. In the embodiment, the inert compound 60 has an angle α with respect to the element side surface 24 of the light emitting element 20 at the boundary.

The boundary functions as a reflector due to the difference in refractive index between the inert compound 60 and the gas layer 70. That is, a reflector having an angle α is formed on the element side surface 24 of the light emitting element 20. The reflectance at the boundary for ultraviolet light of the emission wavelength is, for example, 50% to 100%.

Here, the minimum facing distance H3 of the second subsidiary facing region 83 is equal to or greater than twice the facing distance H2 of the first subsidiary facing region 82. Thus, the boundary between the inert compound 60 and the gas layer 70 is located at a position sufficiently away from the light transmitting member bonding layer 50. Accordingly, the inert compound 60 is prevented from flowing to the position of the light transmitting member bonding layer 50.

### 6. Path of Ultraviolet Light

A path of the ultraviolet light emitted by the light emitting element 20 will be described with reference to FIG. 3. The ultraviolet light emitted from the active layer 92b of the light emitting element 20 is output from the element main surface 23 of the light emitting element 20. The major facing region 81 is filled with the inert compound 60. Accordingly, the light transmitting member 40 is disposed in a direction perpendicular to the element main surface 23 via the inert compound 60. The emitted ultraviolet light is incident on the light transmitting member 40 from the element main surface 23 via the inert compound 60, and is output from the light transmitting member 40 to the outside.

Here, the inert compound 60 is in contact with the element main surface 23, and the inert compound 60 is in contact with the first ceiling surface 42a of the first recess 42 of the light transmitting member 40. Accordingly, the emitted ultraviolet light is prevented from being reflected by the element main surface 23, and is output from the light transmitting member 40.

The ultraviolet light emitted from the active layer 92b of the light emitting element is also output from the element side surface 24 of the light emitting element 20. The first subsidiary facing region 82 is filled with the inert compound 60. The ultraviolet light is emitted from the portion of the element side surface 24 closer to the element main surface 23, and output from the light transmitting member 40 via the inert compound 60 in the first subsidiary facing region 82.

The portion of the element side surface 24 closer to the element main surface 23 is in contact with the inert compound 60, and the inert compound 60 is in contact with the first side wall surface 42b of the first recess 42 of the light transmitting member 40. Accordingly, the emitted ultraviolet light is prevented from being reflected by the element side surface 24, and is output from the light transmitting member 40.

Further, a part of the ultraviolet light emitted from the element side surface 24 is output toward the boundary between the inert compound 60 and the gas layer 70. In the embodiment, a part of the ultraviolet light emitted from the active layer 92b toward the mounting substrate 10 is output toward the boundary between the inert compound 60 and the gas layer 70.

The ultraviolet light having the light emission wavelength is reflected at the boundary between the inert compound 60 and the gas layer 70. Therefore, a part of the ultraviolet light emitted from the element side surface 24 is reflected at the boundary and travels toward the light transmitting member 40. Then, the ultraviolet light is output from the light transmitting member 40 to the outside.

A part of the ultraviolet light emitted from the active layer 92b passes through the boundary between the inert compound 60 and the gas layer 70. However, an amount of ultraviolet light transmitted from the inert compound 60 to the gas layer 70 is extremely small. Further, a part of the ultraviolet light emitted from the active layer 92b is output to the gas layer 70 from a portion of the element side surface 24 that is in contact with the gas layer 70. However, an amount of the ultraviolet light output to the gas layer 70 is extremely small. Thus, the amount of the ultraviolet light output to the gas layer 70 is extremely small. Therefore, even if the light transmitting member bonding layer 50 is made of a material that is not very durable against ultraviolet light, such as silicone resin, the effect is extremely small. Accordingly, the inexpensive materials mentioned above can be used for the light transmitting member bonding layer 50.

### 7. Manufacturing Method for Light Emitting Device 1

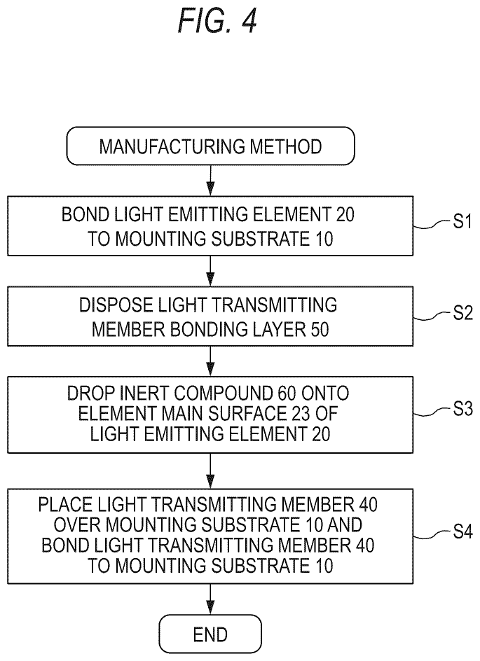

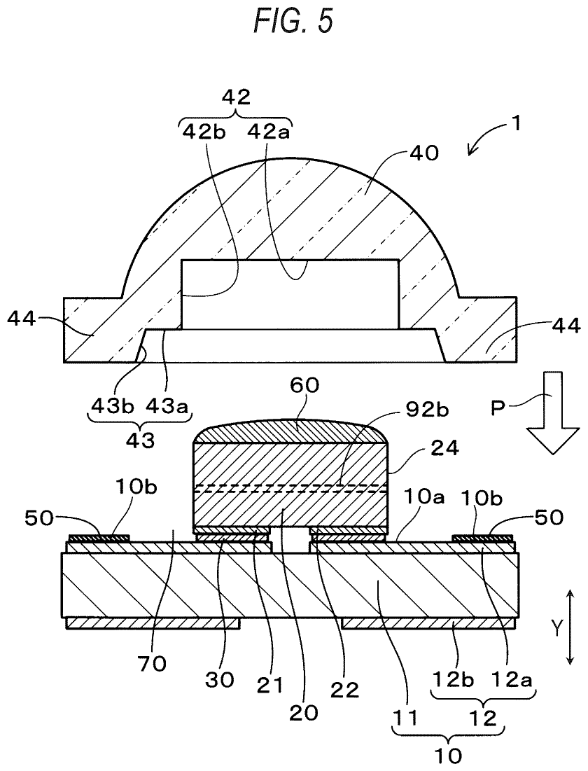

A method for manufacturing the light emitting device 1 will be described with reference to FIGS. 4 and 5. As shown in FIG. 4, in step S1, the light emitting element 20 is bonded to the mounting surface 10a of the mounting substrate 10. Subsequently, in step S2, the light transmitting member bonding layer 50 is disposed on a bonding surface of the mounting surface 10a of the mounting substrate 10 or a bonding surface of the flange portion 44 of the light transmitting member 40.

Subsequently, in step S3, the inert compound 60 is dropped onto the element main surface 23 of the light emitting element 20. At this time, as shown in FIG. 5, the inert compound 60 remains on the element main surface 23 of the light emitting element 20 due to the surface tension. A volume of the dropped inert compound 60 is approximately equal to a total volume of the major facing region 81 and the first subsidiary facing region 82. Specifically, the volume of the dropped inert compound 60 is slightly larger than the total volume of the major facing region 81 and the first subsidiary facing region 82. The volume of the dropped inert compound 60 is sufficiently smaller than a total volume of the major facing region 81, the first subsidiary facing region 82, and the second subsidiary facing region 83.

Subsequently, in step S4 shown in FIG. 4, as indicated by an arrow P in FIG. 5, the light transmitting member 40 is placed over the mounting substrate 10 and bonded thereto. At this time, as the element main surface 23 approaches the first ceiling surface 42a of the first recess 42 of the light transmitting member 40, the inert compound 60 dropped on the element main surface 23 comes into contact with the first ceiling surface 42a and moves gradually toward the element side surface 24. The inert compound 60 that has moved to the element side surface 24 is held in the first subsidiary facing region 82 due to the capillary action between the element side surface 24 and the first side wall surface 42b of the first recess 42 of the light transmitting member 40. In this way, the light emitting device 1 shown in FIG. 1 is completed.

### 8. Operations and Effects

Next, the operation and effect of the light emitting device according to the first embodiment will be described in detail. According to the light emitting device of the first embodiment, the major facing region 81 in which the element main surface 23 and the first ceiling surface 42a of the recess 41 of the light transmitting member 40 face each other, as well as the first subsidiary facing region 82 in which the portion of the element side surface 24 closer to the element main surface 23 and the first side wall surface 42b of the recess 41 of the light transmitting member 40 face each other are filled with the inert compound 60 which is a liquid at ordinary temperature and pressure. Further, the gas layer 70 is formed in the second subsidiary facing region 83 facing the portion of the element side surface 24 closer to the mounting substrate 10. As a result, the gas layer 70 formed in the second subsidiary facing region 83 can prevent capillary action from occurring in the second subsidiary facing region 83, so that the liquid inert compound 60 with which the major facing region 81 and the first subsidiary facing region 82 are filled is prevented from flowing out and held in the major facing region 81 and the first subsidiary facing region 82. Accordingly, it is possible to prevent a decrease in the efficiency of extracting ultraviolet light emitted from the element main surface 23, and to improve the efficiency of extracting ultraviolet light emitted from at least the portion of the element side surface 24 closer to the element main surface 23. Therefore, the efficiency of extracting ultraviolet light from the light emitting device 1 as a whole can be improved.

In the first embodiment, the facing distance H3 in the second subsidiary facing region 83 is longer than the facing distance H2 in the first subsidiary facing region 82. Accordingly, the inert compound 60 is easily held in the major facing region 81 and the first subsidiary facing region 82, and the inert compound 60 is prevented from flowing out to the second subsidiary facing region 83. Therefore, the efficiency of extracting ultraviolet light from the light emitting device 1 as a whole can be further improved.

In the first embodiment, the inert compound 60 is held in the major facing region and the first subsidiary facing region by the capillary action. Accordingly, a holding force of the inert compound 60 in the major facing region 81 and the first subsidiary facing region 82 can be improved, the inert compound 60 with which the major facing region 81 and the first subsidiary facing region 82 are filled can be further prevented from flowing out, and the efficiency of extracting ultraviolet light from the light emitting device 1 as a whole can be further improved.

In the first embodiment, the facing distance H2 of the first subsidiary facing region 82 is longer than the facing distance H1 of the major facing region 81. Accordingly, it is possible to further improve the holding force of the inert compound 60 in the major facing region 81 by the capillary action to further prevent the inert compound 60 from flowing out, and to further improve the efficiency of extracting ultraviolet light from the light emitting device 1 as a whole.

In the first embodiment, the facing distance H1 of the major facing region 81 is 0.1 μm to 500 μm, and the facing distance H2 of the first subsidiary facing region 82 is 0.1 μm to 500 μm. Accordingly, it is possible to prevent the inert compound 60 from flowing out by reliably generating the capillary action in the major facing region 81 and the first subsidiary facing region 82, and to further improve the efficiency of extracting ultraviolet light from the light emitting device 1 as a whole.

In the first embodiment, the arithmetic mean roughness Ra of the surface of the element side surface 24 of the light emitting element 20 forming the first subsidiary facing region 82 is 100 μm or less. Accordingly, the contact angle of the inert compound 60 with respect to the element side surface 24 decreases, and the wettability decreases. As a result, the inert compound 60 can be promoted to be held in the first subsidiary facing region 82 by the capillary action.

In the first embodiment, the light emitting element 20 is formed in a shape that has no chip at the boundary between the element main surface 23 and the element side surface 24. Accordingly, the inert compound 60 held in the major facing region 81 and the first subsidiary facing region 82 can be further prevented from flowing out.

In the first embodiment, the element side surface 24 of the light emitting element 20 and the first side wall surface 42b of the recess 41 are formed in parallel. Accordingly, the inert compound 60 held in the major facing region 81 and the first subsidiary facing region 82 can be prevented from flowing out.

In the first embodiment, a side surface of the active layer 92b of the light emitting element 20 faces the first subsidiary facing region 82 and faces the inert compound 60. Accordingly, as compared with a case where the side surface of the active layer 92b that emits ultraviolet light faces the gas layer 70, the ultraviolet light emitted from the side surface of the active layer 92b is incident on the light transmitting member 40 via the inert compound 60 and is easily output from the light transmitting member 40, so that the efficiency of extracting ultraviolet light from the light emitting device 1 as a whole can be further improved.

In the first embodiment, the length L1 of the first subsidiary facing region 82 in the direction Y perpendicular to the mounting surface 10a of the mounting substrate 10 is longer than a length L2 of the second subsidiary facing region 83 in the direction Y perpendicular to the mounting surface 10a of the mounting substrate. Accordingly, the ultraviolet light emitted from the side surface of the active layer 92b of the light emitting element 20 is incident on the light transmitting member 40 via the inert compound 60 and is easily output from the light transmitting member 40, so that the efficiency of extracting ultraviolet light from the light emitting device 1 as a whole can be further improved.

In the first embodiment, the light emitting element 20 is of a flip chip type in which light is extracted from the surface closer to the element substrate 91 included in the light emitting element 20. Accordingly, as compared to a face-up type, it is possible to further improve the efficiency of extracting ultraviolet light from the light emitting element 20 itself, and as a result, it is possible to further improve the efficiency of extracting ultraviolet light from the light emitting device 1 as a whole.

As described above, according to the first embodiment, it is possible to provide the light emitting device 1 capable of improving the efficiency of extracting ultraviolet light.

### Second Embodiment

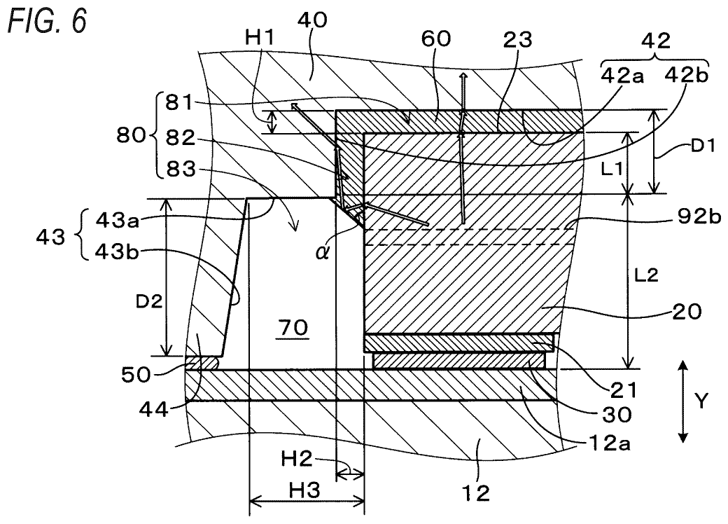

In the first embodiment, as shown in FIG. 3, the first subsidiary facing region 82 faces the side surface of the active layer 92b of the light emitting element 20. Alternatively, as in the second embodiment shown in FIG. 6, the first subsidiary facing region 82 may not face the side surface of the active layer 92b of the light emitting element 20, and the second subsidiary facing region 83 may face the side surface of the active layer 92b of the light emitting element 20. In the second embodiment, the same components as those in the first embodiment are denoted by the same reference numerals, and description thereof is omitted.

In the second embodiment, a part of the ultraviolet light emitted from the active layer 92b of the light emitting element 20 is incident on the inert compound 60 in the first subsidiary facing region 82 from the element side surface 24 of the light emitting element 20 facing the first subsidiary facing region 82 of the light emitting element 20. Then, the light is reflected toward the light transmitting member 40 by the boundary between the inert compound 60 and the gas layer 70, is incident on the light transmitting member 40, and is output to the outside.

According to the second embodiment, an amount of ultraviolet light directly emitted from the side surface of the active layer 92b to the gas layer 70 in the second subsidiary facing region 83 tends to increase in comparison with the first embodiment. A degree of improvement in the efficiency of extracting ultraviolet light from the light emitting device 1 as a whole is lower in comparison with the first embodiment, but it goes without saying that the efficiency of extracting ultraviolet light is improved compared to the case where the inert compound 60 in the first subsidiary facing region 82 is not present. Except for the fact that the degree of improvement in the efficiency of extracting ultraviolet light is reduced, the second embodiment also provides the same effects as the first embodiment.

### Third Embodiment

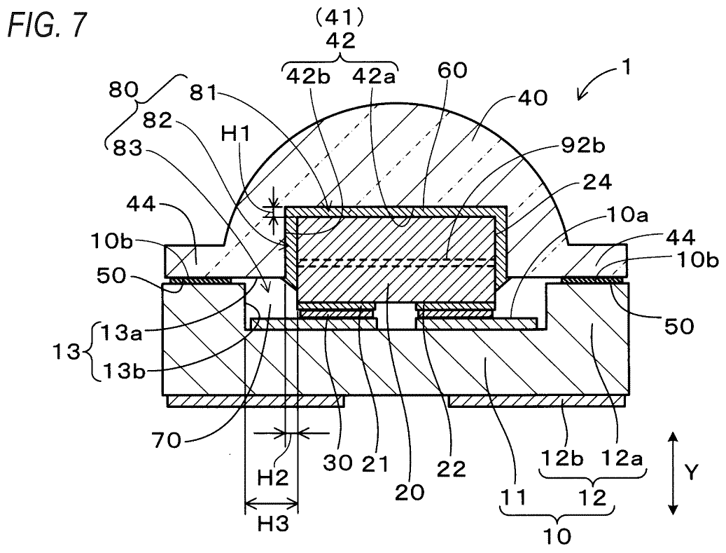

In the first embodiment, as shown in FIG. 1, the outer peripheral edge 10b, which is a bonding portion with the flange portion 44 of the light transmitting member 40, is positioned on the same plane as the mounting surface 10a in the mounting substrate 10, but the present invention is not limited thereto. As in the third embodiment shown in FIG. 7, the mounting surface 10a may be provided at a bottom of a substrate recess 13 formed in a concave shape in the mounting substrate 10, and the outer peripheral edge 10b may be located outside the substrate recess 13 and may not be flush with the mounting surface 10a.

In the third embodiment, a side wall surface 13b of the substrate recess 13 and the element side surface 24 face each other, and a region between the side wall surface 13b and the element side surface 24 serves as the second subsidiary facing region 83. A second ceiling surface 13a, which is an upper surface of the second subsidiary facing region 83, is formed in a planar shape parallel to the mounting surface 10a of the mounting substrate 10. The gas layer 70 is formed in the second subsidiary facing region 83.

As described above, the bonding position between the light transmitting member 40 and the mounting substrate 10 is also located (lower side in FIG. 1) closer to the mounting surface 10a of the mounting substrate 10 than the position of an active layer 92b of the light emitting element 20 in a direction Y perpendicular to the mounting surface 10a of the mounting substrate 10. That is, the light transmitting member bonding layer 50 is positioned closer to the mounting surface 10a of the mounting substrate 10 than the first subsidiary facing region 82. Further, the light transmitting member bonding layer 50 is positioned closer to the mounting surface 10a of the mounting substrate 10 than the position of the active layer 92b. In the third embodiment, the same components as those in the first embodiment are denoted by the same reference numerals, and description thereof is omitted. The third embodiment has the same effects as the first embodiment.

The present invention is not limited to the above-described embodiments, and can be applied to various embodiments without departing from the gist of the present invention.

What is claimed is:

1. A light emitting device that emits ultraviolet light, the light emitting device comprising:
a mounting substrate having a mounting surface;
a light emitting element disposed on the mounting surface of the mounting substrate and configured to emit ultraviolet light, the light emitting element having an element main surface facing a side opposite to the mounting surface and an element side surface adjacent to the element main surface;
a light transmitting member disposed on the mounting surface of the mounting substrate and configured to form an accommodation space in a region facing the mounting surface of the mounting substrate, the light transmitting member having a recess that forms at least a part of the accommodation space and accommodates at least a part of the light emitting element;
an inert compound disposed in the accommodation space and being a liquid at ordinary temperature and pressure; and
a gas layer formed in the accommodation space,
wherein the inert compound is provided to fill a major facing region in which the element main surface of the light emitting element and a first ceiling surface of the recess face each other, and a first subsidiary facing region in which a portion of the element side surface of the light emitting element closer to the element main surface and a first side wall surface of the recess face each other, with the inert compound, and
the gas layer is formed in a second subsidiary facing region that faces a portion of the element side surface of the light emitting element closer to the mounting substrate.

2. The light emitting device according to claim 1,
wherein a facing distance in the second subsidiary facing region is longer than a facing distance in the first subsidiary facing region.

3. The light emitting device according to claim 1,
wherein the inert compound is held in the major facing region and the first subsidiary facing region by capillary action.

4. The light emitting device according to claim 3,
wherein a facing distance of the first subsidiary facing region is longer than a facing distance of the major facing region.

5. The light emitting device according to claim 3,
wherein a facing distance of the major facing region is 0.1 μm to 500 μm, and
a facing distance of the first subsidiary facing region is 0.1 μm to 500 μm.

6. The light emitting device according to claim 3,
wherein arithmetic mean roughness of a surface of the element side surface of the light emitting element forming the first subsidiary facing region is 100 μm or less.

7. The light emitting device according to claim 3,
wherein the light emitting element is formed in a shape that has no chip at a boundary between the element main surface and the element side surface.

8. The light emitting device according to claim 3,
wherein the element side surface of the light emitting element and the first side wall surface of the recess are formed in parallel.

9. The light emitting device according to claim 1,
wherein a side surface of an active layer of the light emitting element faces the first subsidiary facing region and faces the inert compound.

10. The light emitting device according to claim 1,
wherein a length of the first subsidiary facing region in a direction perpendicular to the mounting surface of the mounting substrate is longer than a length of the second subsidiary facing region in the direction perpendicular to the mounting surface of the mounting substrate.

11. The light emitting device according to claim 1,
wherein the light emitting element is of a flip chip type in which light is extracted from a back surface side of an element substrate included in the light emitting element.
